(19) United States
(12) Patent Application Publication
(10) Pub. No.: US 2019/0164726 A1
(43) Pub. Date: May 30, 2019

(54) PLASMA PROCESSING APPARATUS

(71) Applicant: TOKYO ELECTRON LIMITED, Tokyo (JP)

(72) Inventors: Gen TAMAMUSHI, Miyagi (JP); Naoyuki SATOH, Miyagi (JP); Akihiro YOKOTA, Miyagi (JP); Shinji HIMORI, Miyagi (JP)

(73) Assignee: TOKYO ELECTRON LIMITED, Tokyo (JP)

(21) Appl. No.: 16/201,659

(22) Filed: Nov. 27, 2018

(30) Foreign Application Priority Data
Nov. 29, 2017 (JP) 2017-229534

(51) Int. Cl. H01J 37/32

(52) U.S. Cl. CPC H01J 37/32495; H01J 2237/334

(57) ABSTRACT

A plasma processing apparatus includes a processing chamber in which plasma is generated, and a protection target member which is provided in the processing chamber and needs to be protected from consumption by the plasma. The protection target member is made of a material having a property of integrating radicals and/or anions or a protective layer containing the material is provided on a surface of the protection target member.

### CROSS-REFERENCE TO RELATED APPLICATIONS

This application claims priority to Japanese Patent Application No. 2017-229534 filed on Nov. 29, 2017, the entire contents of which are incorporated herein by reference.

### FIELD OF THE INVENTION

The present disclosure relates to a plasma processing apparatus.

### BACKGROUND OF THE INVENTION

Conventionally, there is known a plasma processing apparatus having a bonding layer for bonding a base (susceptor) and an electrostatic chuck between the base and the electrostatic chuck. In this plasma processing apparatus, the bonding layer is consumed from a side portion thereof by plasma. In the plasma processing apparatus, when the side portion of the bonding layer is decreased by consumption, a space is generated. Since it is not possible to sufficiently control a temperature of the portion where the space is generated, in-plane uniformity of an etching rate is decreased. Therefore, in the plasma processing apparatus, an O-ring to be in contact with a lower portion of the electrostatic chuck is provided to cover exposed surfaces of the base and the bonding layer. Accordingly, the contact with the plasma is avoided and the bonding layer is protected (see, e.g., Japanese Patent Application Publication No. 2014-053482).

However, due to a high cost of the O-ring, a manufacturing cost of the plasma processing apparatus is increased. In addition, the O-ring is consumed by the plasma and, thus, the time and effort is required for replacing the O-ring.

The problem of consumption by the plasma is not limited to the bonding layer. It occurs in all the members to be protected from consumption by the plasma.

### SUMMARY OF THE INVENTION

In accordance with an aspect, there is provided a plasma processing apparatus including a processing chamber and a protection target member. Plasma is generated in the processing chamber, and the protection target member is provided in the processing chamber and needs to be protected from consumption by the plasma. The protection target member is made of a material having a property of integrating radicals and/or anions or a protective layer containing the material is provided on a surface of the protection target member.

### BRIEF DESCRIPTION OF THE DRAWINGS

The objects and features of the present disclosure will become apparent from the following description of embodiments, given in conjunction with the accompanying drawings, in which:

FIG. 1 is a cross sectional view showing a schematic configuration of a plasma processing apparatus according to a first embodiment;

FIG. 2 is a schematic cross sectional view showing an example of a configuration of principal parts of a base and an electrostatic chuck;

FIG. 3 schematically shows a structure of hydrotalcite;

FIG. 4 shows a weight change before and after plasma processing;

FIG. 5A shows a measurement result of an etching rate on a semiconductor wafer;

FIG. 5B is a graph showing changes in the etching rate;

FIG. 5C is a graph showing the changes in the etching rate;

FIG. 6A shows a measurement result of an etching rate on a semiconductor wafer;

FIG. 6B is a graph showing changes in the etching rate;

FIG. 6C is a graph showing the changes in the etching rate;

FIG. 7 shows a range in which two protective layers are formed;

FIGS. 8A and 8B show an example of a sequence of forming a protective layer;

FIG. 9 shows flow of plasma processing performed in an evaluation test;

FIG. 10 explains measurement of a thickness of a protective layer;

FIG. 11 shows changes in a height of the protective layer;

FIG. 12A is a graph showing changes in etching rate;

FIG. 12B is a graph showing the changes in the etching rate with respect to plasma processing time;

FIG. 13 is a graph showing changes in the amount of contamination with respect to plasma processing time; and

FIG. 14 is a graph showing changes in the amount of particles with respect to the plasma processing time.

### DETAILED DESCRIPTION OF THE EMBODIMENTS

Hereinafter, embodiments of a plasma processing apparatus of the present disclosure will be described in detail with reference to the accompanying drawings. Like reference numerals will be given to like or corresponding parts throughout the drawings. The embodiments are not intended to limit the present disclosure. The embodiments may be appropriately combined without contradicting processing contents.

### First Embodiment

<Configuration of Plasma Processing Apparatus>

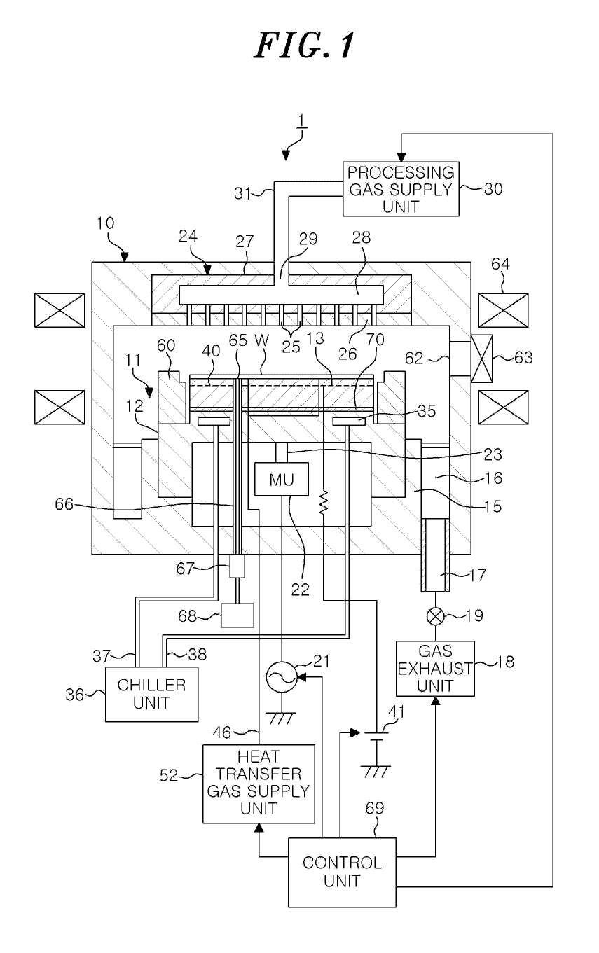

First, a schematic configuration of a plasma processing apparatus according to an embodiment will be described. The plasma processing apparatus is a system for performing plasma processing on a target object such as a semiconductor wafer (hereinafter, referred to as “wafer”) or the like. In the present embodiment, the case of performing plasma etching as the plasma processing will be described as an example. FIG. 1 is a cross sectional view showing a schematic configuration of a plasma processing apparatus according to a first embodiment.

The plasma processing apparatus 1 includes an airtight cylindrical processing chamber 10 that is electrically grounded and made of a metal, e.g., aluminum or stainless steel. A cylindrical mounting table (lower electrode) 11 for mounting thereon a wafer W as a target substrate is provided in the processing chamber 10. The mounting table 11 includes a mounting table main body 12 made of a conductive material, e.g., aluminum or the like, and an electrostatic chuck 13 provided on the mounting table main body 12 to attract the wafer W and made of an insulating material, e.g., Al₂O₃ or the like. The mounting table 11 and the electrostatic chuck 13 are bonded by a bonding layer 70. The mounting table main body 12 is supported by a cylindrical support 15 extending vertically upward from a bottom portion of the processing chamber 10 through an insulator.

A gas exhaust passage 16 is formed between a sidewall of the processing chamber 10 and the cylindrical support 15. A gas exhaust line 17 communicating with a bottom portion of the gas exhaust passage 16 is connected to a gas exhaust unit 18. The gas exhaust unit 18 includes a vacuum pump and decreases a pressure in the processing chamber 10 to a predetermined vacuum level. The gas exhaust line 17 has an automatic pressure control valve 19 that is a variable butterfly valve. The pressure in the processing chamber 10 is controlled by the automatic pressure control valve 19.

A high frequency power supply 21 for applying a high frequency voltage for plasma generation and for ion attraction is electrically connected to the mounting table main body 12 via a matching unit (MU) 22 and a power feed rod 23. The high frequency power supply 21 applies a high frequency power having a predetermined high frequency, e.g., 60 MHz, to the mounting table 11. A plurality of high frequency power supplies 21 may be provided to supply a plurality of high frequency powers having different frequencies to the mounting table 11. For example, a plurality of high frequency power supplies 21 may be provided to supply a high frequency power for plasma generation and a high frequency power for attracting ions to the wafer W to the mounting table 11.

A shower head 24 serving as a ground electrode is provided at a ceiling portion of the processing chamber 10. A high frequency voltage is applied between the mounting table 11 and the shower head 24 by the high frequency power supply 21. The shower head 24 includes an electrode plate 26 as a bottom surface having a plurality of gas injection holes 25 and an electrode holder 27 for detachably holding the electrode plate 26. A buffer space 28 is provided in the electrode holder 27. A gas supply line 31 from a processing gas supply unit 30 is connected to a gas inlet 29 of the buffer space 28.

An annular coolant path 35 extending in, e.g., a circumferential direction, is provided in the mounting table main body 12. A coolant, e.g., cooling water, of a predetermined temperature is supplied from a chiller unit 36 through lines 37 and 38 and circulated in the coolant path 35. Accordingly, the mounting table main body 12 is cooled to a predetermined temperature.

The electrostatic chuck 13 provided on the upper portion of the mounting table main body 12 has a disc shape having an appropriate thickness. An electrode plate 40 made of a conductive material such as tungsten or the like is embedded in the electrostatic chuck 13. A DC power supply 41 is electrically connected to the electrode plate 40. By applying a DC voltage from the DC power supply 41 to the electrode plate 40, the wafer W can be attracted and held on the electrostatic chuck 13 by Coulomb force.

As described above, heat of the mounting table main body 12 cooled to a predetermined temperature is transferred to the wafer W attracted on the upper surface of the electrostatic chuck 13 via the electrostatic chuck 13. In that case, a heat transfer gas such as He or the like is supplied from a heat transfer gas supply unit 52 toward a backside of the wafer W attracted on the upper surface of the electrostatic chuck 13 through a first gas supply line 46 in order to efficiently transfer the heat to the wafer W even if the pressure in the processing chamber 10 is decreased.

As described above, the heat of the mounting table main body 12 is transferred to the wafer W via the electrostatic chuck 13. At this time, however, the electrostatic chuck 13 is deformed by temperature changes, which may deteriorate flatness of the upper surface of the electrostatic chuck 13. If the flatness of the upper surface of the electrostatic chuck 13 deteriorates, the wafer W cannot be reliably held. Therefore, it is preferable to allow the bonding layer 70 to absorb the deformation of the electrostatic chuck 13, which is caused by the temperature changes, and prevent the deterioration of the flatness of the upper surface of the electrostatic chuck 13 by controlling the thickness of the bonding layer 70. Accordingly, it is preferable to set the thickness of the bonding layer 70 to 60 μm or more when the diameter of the wafer W is 200 mm and to 90 to 150 μm when the diameter of the wafer W is 300 mm.

An annular focus ring 60 is provided on the mounting table 11 to surround the electrostatic chuck 13. A gate valve 63 for opening and closing a loading/unloading port 62 for the wafer W is attached to the sidewall of the processing chamber 10. A magnet 64 extending annularly or concentrically is provided around the processing chamber 10.

A through-hole 65 formed through the mounting table main body 12 constituting the mounting table 11, the bonding layer 70, and the electrostatic chuck 13. A pusher pin 66 that is electrically grounded via a resistor or an inductance is inserted into the through-hole 65. Although FIG. 1 shows a single through-hole 65 and a single pusher pin 66, three or more through-holes 65 and three or more pusher pins 66 are arranged at a regular interval in the circumferential direction of the mounting table 11. Each of the pusher pins 66 is connected to an air cylinder 68 via an extensible/contractible bellows 67 that airtightly seals the processing chamber 10. The pusher pin 66 is vertically moved by the air cylinder 68 when the wafer W is transferred to and from the electrostatic chuck 13 through a transfer unit of a load-lock chamber. An operation of loading the wafer W into the processing chamber 10 will be described. The gate valve 63 is opened, and the wafer W is loaded into the processing chamber 10 through the loading/unloading port 62 by the transfer unit. Next, the pusher pins 66 are raised through the through-holes 65 to support the backside of the wafer W and lift the wafer W from the transfer unit. Then, the transfer unit returns to the load-lock chamber through the loading/unloading port 62, and the pusher pins 66 are lowered through the through-holes 65. Accordingly, the wafer W is mounted on the electrostatic chuck 13. Finally, the gate valve 63 is closed and the transfer of the wafer W into the processing chamber 10 is completed. An operation of unloading the wafer W from the processing chamber 10 will be described. The gate valve 63 is opened, and the pusher pins 66 are raised through the through-holes 65 to lift the wafer W from the electrostatic chuck 13. The transfer unit enters the processing chamber 10 through the loading/unloading port 62 and reaches a position below the wafer W supported on the pusher pins 66. Next, the pusher pins 66 are lowered through the through-holes 65, and the wafer W is mounted on the transfer unit. Thereafter, the transfer unit returns to the load-lock chamber through the loading/unloading port 62 and the unloading of the wafer W from the processing chamber 10 is completed.

In the processing chamber 10 of the plasma processing apparatus, a horizontal magnetic field directed in one direction is generated by the magnet 64 and, also, a vertical RF electric field is generated by the high frequency voltage applied between the mounting table 11 and the shower head 24. Accordingly, magnetron discharge is performed through the processing gas in the processing chamber 10, and high-density plasma is generated from the processing gas near the surface of the mounting table 11.

The operations of the respective components of the plasma processing apparatus 1, such as the gas exhaust unit 18, the high frequency power supply 21, the processing gas supply unit 30, the DC power supply 41 for the electrostatic chuck 13, the heat transfer gas supply unit 52, and the like are controlled by a control unit 69.

<Configuration of Principal Parts of the Mounting Table 11 and the Electrostatic Chuck 13>

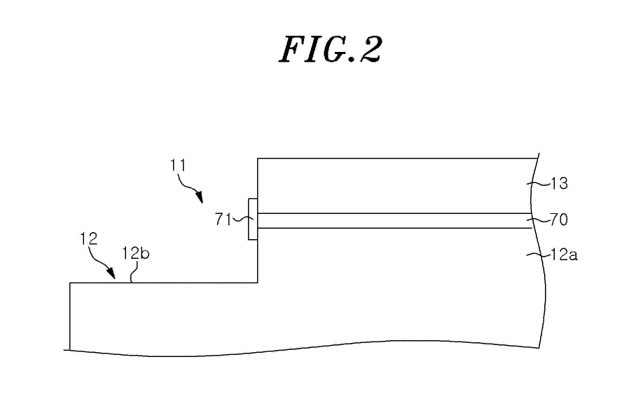

Next, the configuration of the principal parts of the mounting table 11 and the electrostatic chuck 13 will be described. FIG. 2 is a schematic cross sectional view showing an example of the configuration of the principal parts of the base and the electrostatic chuck.

The mounting table 11 includes the mounting table main body 12 made of a conductive material, e.g., aluminum or the like, and the electrostatic chuck 13 provided on the mounting table main body 12 to attract the wafer W and made of an insulating material, e.g., Al₂O₃ or the like. The mounting table main body 12 has a substantially columnar shape with an upper and a lower surface directed vertically. A central portion 12a of the upper surface is higher than a peripheral portion 12b. The central portion 12a has substantially the same size as that of the wafer W.

The electrostatic chuck 13 is provided above the central portion 12a of the mounting table 11. The mounting table 11 and the electrostatic chuck 13 are bonded by the bonding layer 70. The bonding layer 70 reduces stress between the electrostatic chuck 13 and the mounting table 11 and bonds the mounting table 11 and the electrostatic chuck 13. The bonding layer 70 is made of, e.g., an elastomer such as silicone resin, acrylic, epoxy or the like.

In the plasma processing apparatus 1, when plasma etching is performed, a chain atomic bond of an elastomer forming the bonding layer 70 is attacked by radicals or anions. Accordingly, in the plasma processing apparatus 1, the elastomer becomes low-molecular, and the bonding layer 70 is consumed from a side portion thereof. In the plasma processing apparatus 1, when the side portion of the bonding layer 70 is reduced by the consumption, a space is generated in the side portion of the bonding layer 70. In the plasma processing apparatus 1, it is not possible to sufficiently control a temperature of the electrostatic chuck 13 in the portion where the space is generated and, thus, the in-plane uniformity of the etching rate deteriorates.

Therefore, conventionally, in the plasma processing apparatus 1, a maintenance operation is performed at a regular interval. For example, in the plasma processing apparatus 1, the maintenance operation of replacing the electrostatic chuck 13 in response to the consumption of the bonding layer 70 and forming the bonding layer 70 again is performed. In the plasma processing apparatus 1, if the maintenance operation is required in at short time intervals, the time and effort for the maintenance operation is increased and a maintenance cost of the plasma processing apparatus 1 is also increased. Further, in the plasma processing apparatus 1, if the maintenance operation is required at short time intervals, downtime in which the plasma processing cannot be performed is increased and the productivity is decreased.

Therefore, in the plasma processing apparatus 1, a protection target component in the processing chamber 10 which should be protected from the consumption by the plasma is made of a material having a property of integrating radicals and/or anions, or a protective layer 71 containing the corresponding material is provided on a surface of the protection target component. The material having the property of integrating the radicals and/or the anions may be, e.g., hydrotalcite, inorganic nanosheet, layered niobium titanate, mineral having an ion adsorption property, or the like.

In the plasma processing apparatus 1 according to the embodiment, the protective layer 71 containing hydrotalcite is provided on a side surface of the bonding layer 70. The protective layer 71 is made of, e.g., a material obtained by adding hydrotalcite to silicone resin. The addition amount of hydrotalcite may be, e.g., within a range from 0.5 to 90 vol %, preferably from 0.5 to 40 vol %, and more preferably from 5 to 15 vol % in volume percent concentration.

Hydrotalcite is, e.g., a compound represented by the following formula (1).

Mg₁₋ₓAlₓ(OH)₂(Cl)_{x-ny}.(Aⁿ⁻)_{y}.mH₂O (1)

(Here, x is a positive number satisfying 0.15<x<0.34; Aⁿ⁻ is an anion of n valency other than Cl⁻; y is a positive number; and m is a positive number satisfying 0.1<m<0.7).

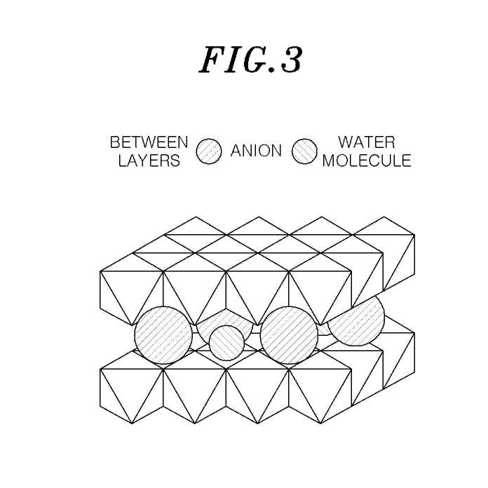

FIG. 3 schematically shows a structure of hydrotalcite. Hydrotalcite is an Mg/Al-based layered compound, and has a layered structure. Further, hydrotalcite has a property of integrating anions between layers. For example, when the processing gas such as CHF₃, CF₄ or the like is converted into plasma, hydrotalcite adsorbs F and does not release the adsorbed F. Hydrotalcite is described in detail in, e.g., Japanese Patent Application Publication No. 2009-178682.

In the plasma processing apparatus 1 according to the embodiment, the consumption of the bonding layers 70 can be suppressed by providing the protective layer 71 containing hydrotalcite on the side surface of the bonding layer 70. This is because hydrotalcite adsorbs F and, thus, the density of F near the side portion of the bonding layer 70 is decreased and the consumption speed is decreased.

### TEST EXAMPLE

Hereinafter, a specific example of the evaluation test that has been conducted by the present inventors to explain the above-described effect will be described. First, specific examples of the evaluation test of examining the effect of suppressing consumption of silicone resin will be described. In the evaluation test, two evaluation samples, i.e., an evaluation sample A containing only silicone resin and an evaluation sample B containing silicon resin and hydrotalcite, were prepared. In the evaluation sample B, 10 vol % of hydrotalcite was contained in the silicone resin. The two evaluation samples A and B have a size of 30 mm×30 mm. In the evaluation test, a plurality of evaluation samples A and a plurality of evaluation samples B were prepared, and plasma etching as plasma processing was performed while varying concentration of the processing gas. As for a processing gas for plasma etching, a mixed gas of CF₄/O₂ was used, and a flow rate ratio of CF₄ and O₂ was varied.

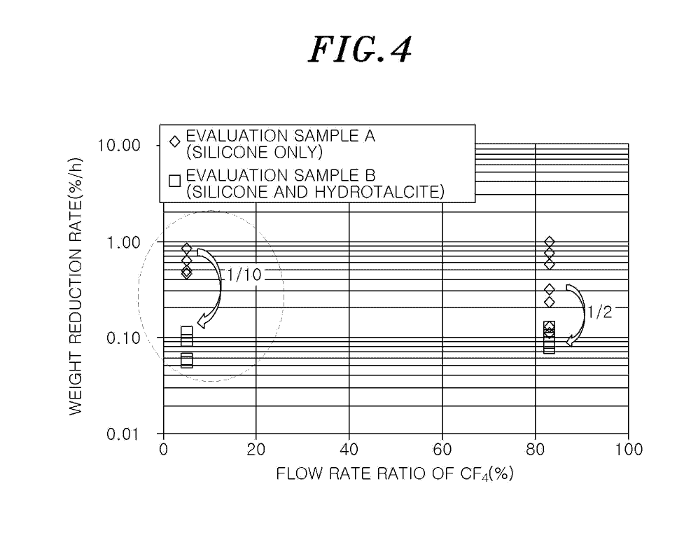

FIG. 4 shows weight changes before and after the plasma processing. FIG. 4 shows the weight changes before and after the plasma processing of the evaluation samples A and B. As shown in FIG. 4, when the flow rate ratio of CF₄ was 5%, the weight changes were suppressed to about 1/10 due to the presence of hydrotalcite. When the flow rate ratio of CF₄ was 85%, the weight changes were suppressed to about ½ due to the presence of hydrotalcite.

In the plasma processing, the consumption of silicone resin can be suppressed due to the presence of hydrotalcite.

Next, a specific example of an evaluation test of examining an F adsorption effect of hydrotalcite will be described. In the evaluation test, three evaluation samples, i.e., an evaluation sample A containing only silicone resin (no hydrotalcite), an evaluation sample B containing silicon resin and hydrotalcite, and an evaluation sample C having hydrotalcite coated on the surface of silicone resin, were prepared. In the evaluation sample B, 10 vol % of hydrotalcite was contained in the silicone resin. The three evaluation samples A to C have a size of 5 mm×5 mm. In the evaluation test, a blanket having an oxide film was used as a wafer W, and the plasma etching was performed in a state where the three evaluation samples A to C were provided on the surface of the wafer W. As for a processing gas for plasma etching, a mixed gas of CF₄/Ar/O₂ was used.

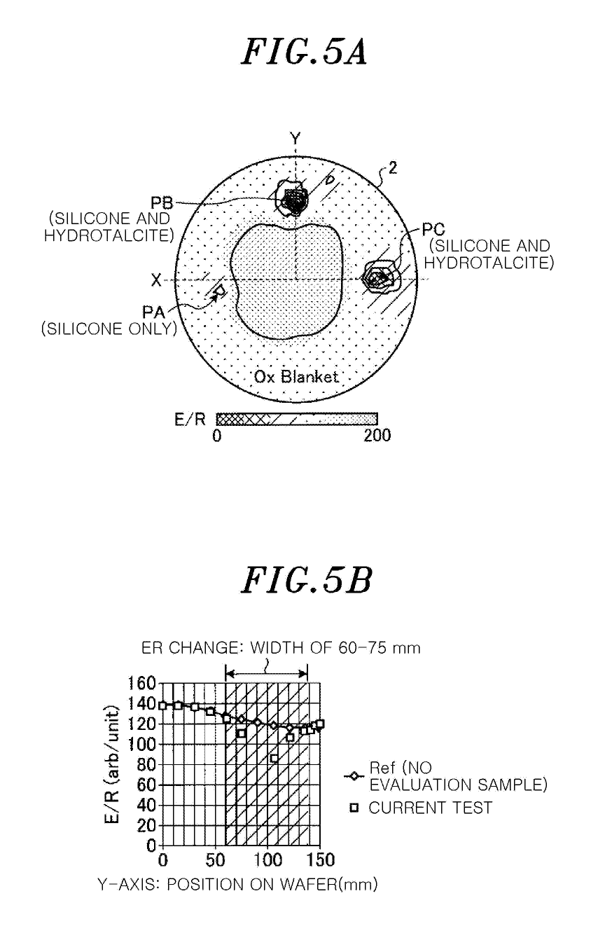

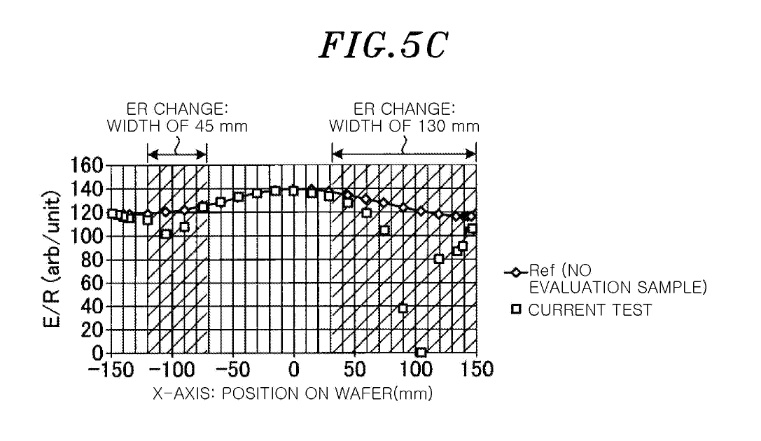

FIG. 5A shows a measurement result of an etching rate on the semiconductor wafer. In FIG. 5A, an etching rate (E/R) at each position of the wafer W is shown in different patterns. In FIG. 5A, there are illustrated positions of measurement points on the wafer W, i.e., a measurement point PA where the evaluation sample A is provided, a measurement point PB where the evaluation sample B is provided, and a measurement point PC where the evaluation sample C is provided. The etching rate in the vicinity of the measurement point PA where the evaluation sample A is provided is substantially the same as that in its surrounding area. The evaluation sample A contains only silicone resin. From this, it is clear that the variation in the etching rate is small in the case of containing only silicone resin. On the other hand, the etching rate in the vicinity of the measurement point PB where the evaluation sample B is provided and the etching rate in the vicinity of the measurement point PC where the evaluation sample C is provided are lower than that in its surrounding areas. In the evaluation sample B and the evaluation sample C, hydrotalcite is contained in or coated on silicone resin. From this, it is clear that hydrotalcite decreases the etching rate.

FIGS. 5B and 5C are graphs showing changes in the etching rate. FIG. 5B shows the changes in the etching rate along the Y-axis of FIG. 5A in a state where the center of the wafer W is set to 0. FIG. 5C shows the change in the etching rate along the X-axis of FIG. 5A in a state where the center of the wafer W is set to 0. The X-axis is slightly deviated from the measurement point PA where the evaluation sample A is provided.

In FIGS. 5B and 5C, the etching rate measured in the case of performing the plasma etching on the wafer W in a state where the evaluation samples A to C were provided on the surface of the wafer W is shown as “current test”. Further, in FIGS. 5B and 5C, the etching rate measured in the case of performing the plasma etching on the wafer W without providing the evaluation samples A to C is shown as “Ref (no evaluation sample)”.

As shown in FIG. 5B, the etching rate is considerably decreased in the vicinity of the position of the measurement point PB where the evaluation sample B containing hydrotalcite is provided (in the vicinity of +110 mm). The decrease in the etching rate occurs at a width of 60 to 75 mm.

As shown in FIG. 5C, the etching rate is slightly decreased in the vicinity of the position of the measurement point PA where the evaluation sample A containing only silicone resin is provided (in the vicinity of −110 mm). The decrease in the etching rate occurs at a width of 45 mm. In addition, the etching rate is considerably decreased in the vicinity of the position of the measurement point PC where the evaluation sample C having hydrotalcite coated on the surface of silicone resin is provided (in the vicinity of +110 mm). The decrease in the etching rate occurs at a width of 130 mm.

As can be seen from FIGS. 5A to 5C, the etching rate is decreased in the vicinity of the evaluation sample B and the evaluation sample C because F is adsorbed by hydrotalcite.

Next, plasma etching was performed in a state where three evaluation samples A to C were provided on a surface of a wafer W made of polysilicon resin. As for a processing gas for plasma etching, a mixed gas of CF₄/O₂ was used.

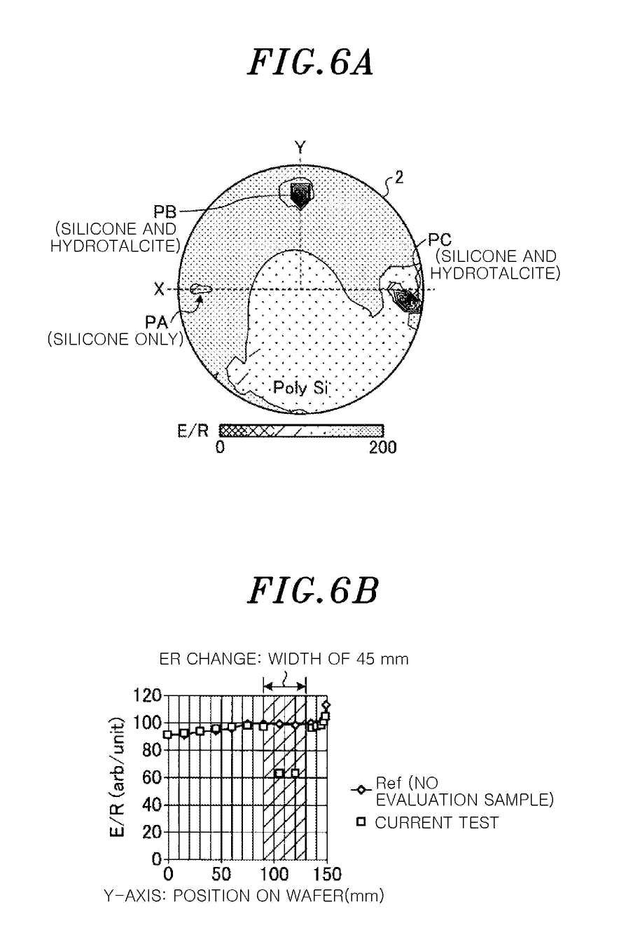

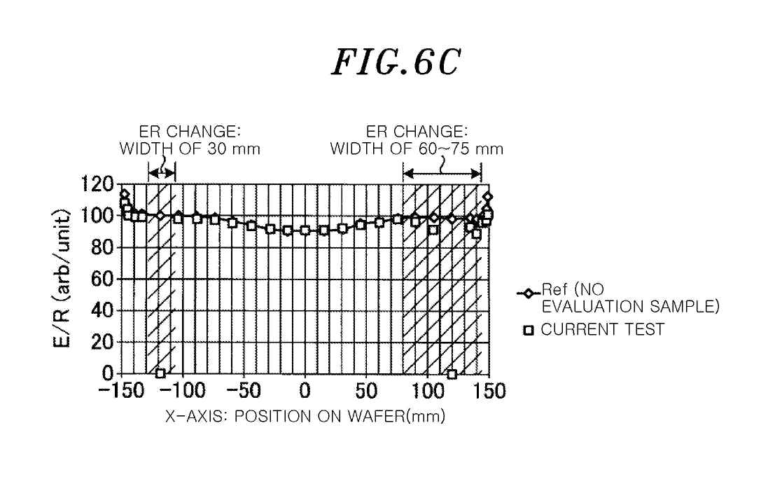

FIG. 6A shows a measurement result of an etching rate on the semiconductor wafer. In FIG. 6A, an etching rate (E/R) at each position of the wafer W made of polysilicon resin is shown in different patterns. In FIG. 6A, there are illustrated positions of measurement points on the wafer W, i.e., the measurement point PA where the evaluation sample A is provided, the measurement point PB where the evaluation sample B is provided, and the measurement point PC where the evaluation sample C is provided. The etching rate in the vicinity of the measurement point PA where the evaluation sample A is provided is substantially the same as that in its surrounding area. The evaluation sample A contains only silicone resin. From this, it is clear that the variation in the etching rate is small in the case of containing only silicon resin even in the case of polysilicon resin. On the other hand, the etching rate in the vicinity of the measurement point PB where the evaluation sample B is provided and the etching rate in the vicinity of the measurement point PC where the evaluation sample C is provided are lower than that in its surrounding areas. In the evaluation sample B and the evaluation sample C, hydrotalcite is contained in or coated on silicone resin. From this, it is clear that hydrotalcite decreases the etching rate even in the case of polysilicon resin.

FIGS. 6B and 6C are graphs showing the changes in the etching rate. FIG. 6B shows the changes in the etching rate along the Y-axis of FIG. 6A in a state where the center of the wafer W is set to 0. FIG. 6B shows the changes in the etching rate along the X-axis of FIG. 6A in a state where the center of the wafer W is set to 0.

In FIGS. 6B and 6C, the etching rate measured in the case of performing the plasma etching on the wafer W in a state where the evaluation samples A to C were provided on the surface of the wafer W is shown as “current test”. Further, in FIGS. 6B and 6C, the etching rate measured in the case of performing the plasma etching on the wafer W without providing the evaluation samples A to C is shown as “Ref (no evaluation sample)”.

As shown in FIG. 6B, the etching rate is considerably decreased in the vicinity of the position of the measurement point PB where the evaluation sample B containing hydrotalcite was provided (in the vicinity of +110 mm). The decrease in the etching rate occurs at a width of 45 mm.

As shown in FIG. 6C, the etching rate is slightly decreased in the vicinity of the position of the measurement point PA where the evaluation sample A containing only silicone resin was provided (in the vicinity of −110 mm). The decrease in the etching rate occurs at a width of 30 mm. In addition, the etching rate is considerably decreased in the vicinity of the position of the measurement point PC where the evaluation sample C having hydrotalcite coated on a surface of silicone resin was provided (in the vicinity of +110 mm). The decrease in the etching rate occurs at a width of 60 to 75 mm.

From FIGS. 6A to 6C, it is clear that the etching rate is decreased in the vicinity of the evaluation sample B and the evaluation sample C because F is adsorbed by hydrotalcite.

Next, a specific example of an evaluation test of examining an effect of protecting the bonding layer 70 by the protective layer 71 containing hydrotalcite will be described. In the evaluation test, the protection effect was examined by forming two protection layers 71, i.e., a protection layer 71a containing no hydrotalcite and a protection layer 71b containing hydrotalcite, on two ranges of the surface of the bonding layer 70 which are obtained by dividing the side surfaces (circumferential surfaces) of the mounting table 11 and the electrostatic chuck 13 into two halves. In the protective layer 71b, 10 vol % of hydrotalcite was contained in silicone resin.

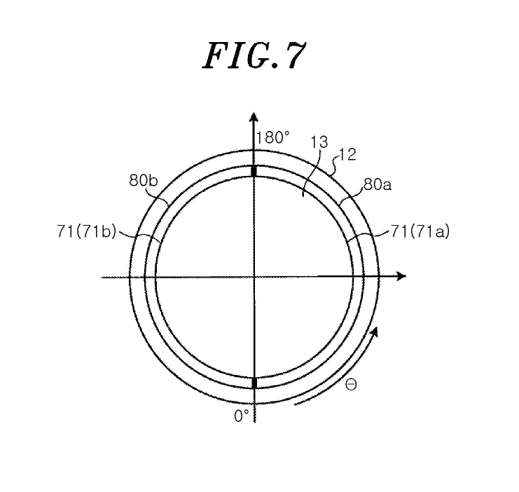

FIG. 7 shows the ranges in which two protective layers are formed. FIG. 7 is a top view of the mounting table 11 and the electrostatic chuck 13 which is viewed from the top. In FIG. 7, there are illustrated a range 80a, in which the protective layer 71a containing no hydrotalcite is formed, and a range 80b, in which the protective layer 71b containing hydrotalcite is formed, on the side surfaces of the mounting table 11 and the electrostatic chuck 13. For example, as shown in FIG. 7, the positions of the side surfaces of the mounting table 11 and the electrostatic chuck 13 are indicated by an angle θ from the center in a state where a lower position with respect to the center of the mounting table 11 and the center of the electrostatic chuck 13 is set to 0°. In that case, the protective layer 71a is formed in the range of the angle θ from 0° to 180°. The protective layer 71b is formed in the range of the angle θ from 180° to 360°.

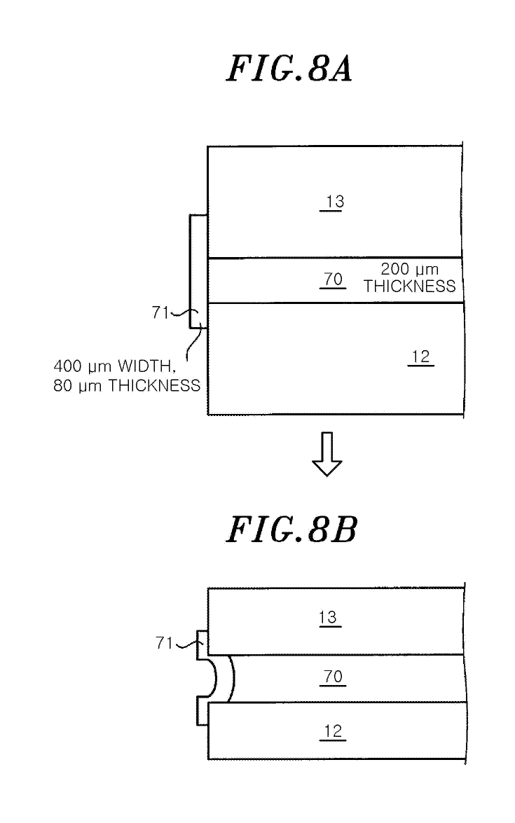

Here, a sequence of forming the protective layer 71 will be described. FIGS. 8A and 8B show an example of the sequence of forming the protective layer. For example, when the bonding layer 70 has a thickness of 200 μm, the protective layer 71 is formed with a width of 400 μm and a thickness of 80 μm on the side surface of the bonding layer 70. The width and the thickness of the protective layer 71 are merely examples and not limited thereto. The width of the protective layer 71 is set to be greater than that of the bonding layer 70 so that the bonding layer 70 can be covered. The thickness of the protective layer 71 is set enough to sufficiently keep the property of integrating F during the plasma processing.

The shape of the side surface of the formed protective layer 71 is not limited to the flat shape without a stepped portion as shown in FIG. 8A. As shown in FIG. 8B, the bonding layer 70 may be partially depressed.

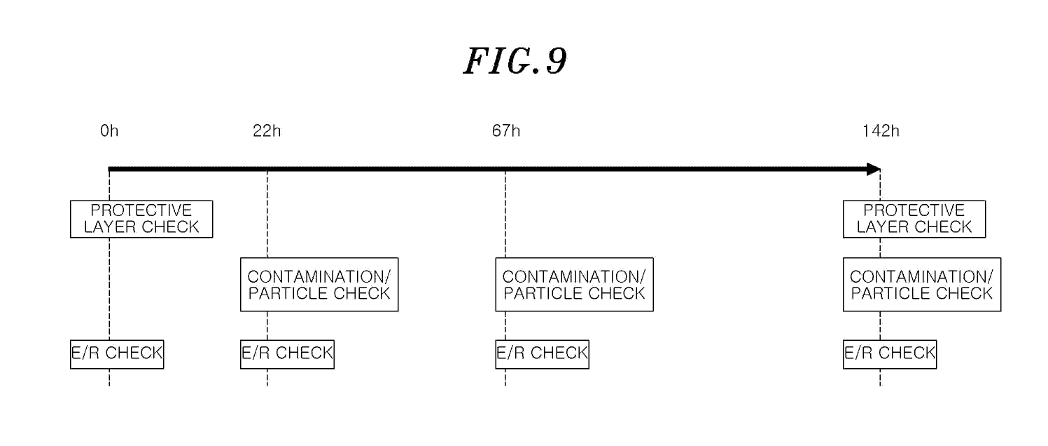

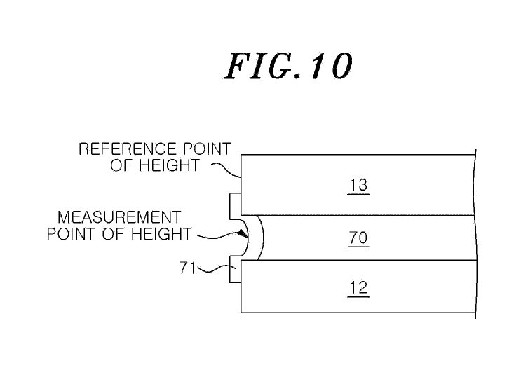

In the evaluation test, the plasma processing was repeatedly performed by using the plasma processing apparatus 1 having the protective layer 71, and the changes in the protective layer 71 was evaluated. FIG. 9 shows the flow of the plasma processing performed in the evaluation test. In the evaluation test, the plasma processing was performed for 162 hours by using the plasma processing apparatus 1 having a new protective layer 71. In the evaluation test, the thickness of the protective layer 71 was measured in a state where the protective layer 71 was newly formed (0 h) and in a state where the plasma processing was performed for 142 hours (142 h). FIG. 10 explains the measurement of the thickness of the protective layer. In the evaluation test, a height of the surface of the protective layer 71 with reference to the side surface (height: 0) of the electrostatic chuck 13 was measured as the thickness of the protective layer 71. Further, in the evaluation test, the etching rate, the amount of contamination, the number of particles, and the like were measured in a state where the protective layer 71 was newly formed (0 h) and in a state where the plasma processing was performed for 22 hours (22 h), 67 hours (67 h) and 142 hours (142 h).

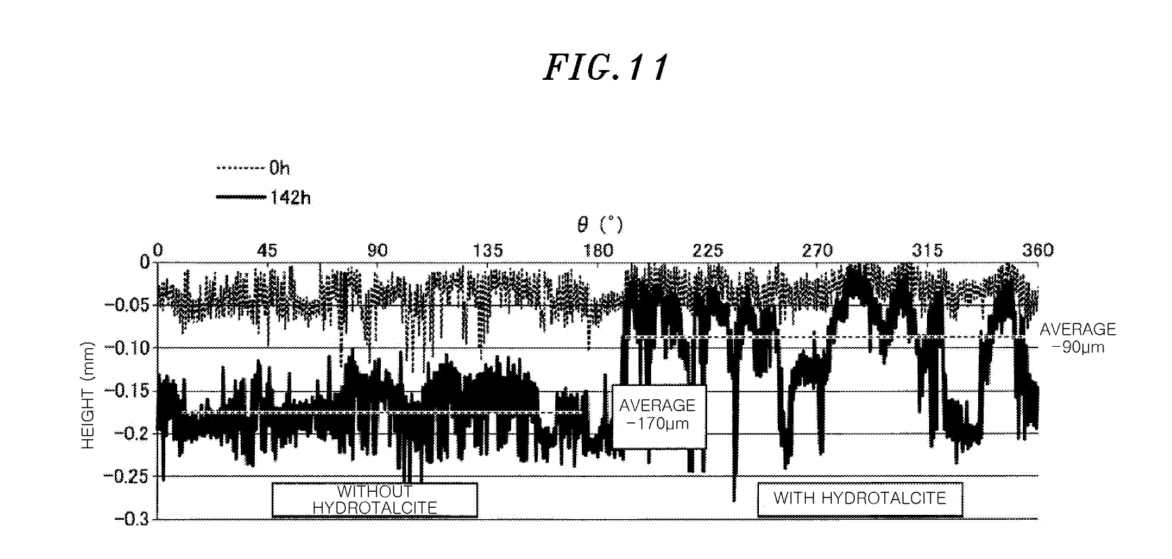

FIG. 11 shows changes in the height of the protective layer. The height of the protective layer 71 was measured at the position of the angle θ in a state where the protective layer 71 was newly formed (0 h) and in a state where the plasma processing was performed for 142 hours (142 h).

In the state of 0 h, the height of the protective layer 71 at the angle θ from 0° to 180° where the protective layer 71a containing no hydrotalcite was formed was substantially the same as that at the angle θ from 180° to 360° where the protective layer 71b containing hydrotalcite was formed. In other words, in a state where the protective layer 71 was newly formed, the height of the protective layer 71a was substantially the same as that of the protective layer 71b.

On the other hand, in the state of 142h, at the angle θ from 0° to 180° where the protective layer 71a containing no hydrotalcite was formed, the height was considerably decreased and the average height was −170 μm. At the angle θ from 180° to 360° where the protective layer 71b containing hydrotalcite was formed, the decrease in the height was small and the average height was −90 μm. Although the height was considerably decreased locally at the angle θ from 180° to 360°, this is because the amount of hydrotalcite was not uniform and locally small.

As can be seen from FIG. 11, the protective layer 71b containing hydrotalcite can suppress the decrease in the bonding layer 70.

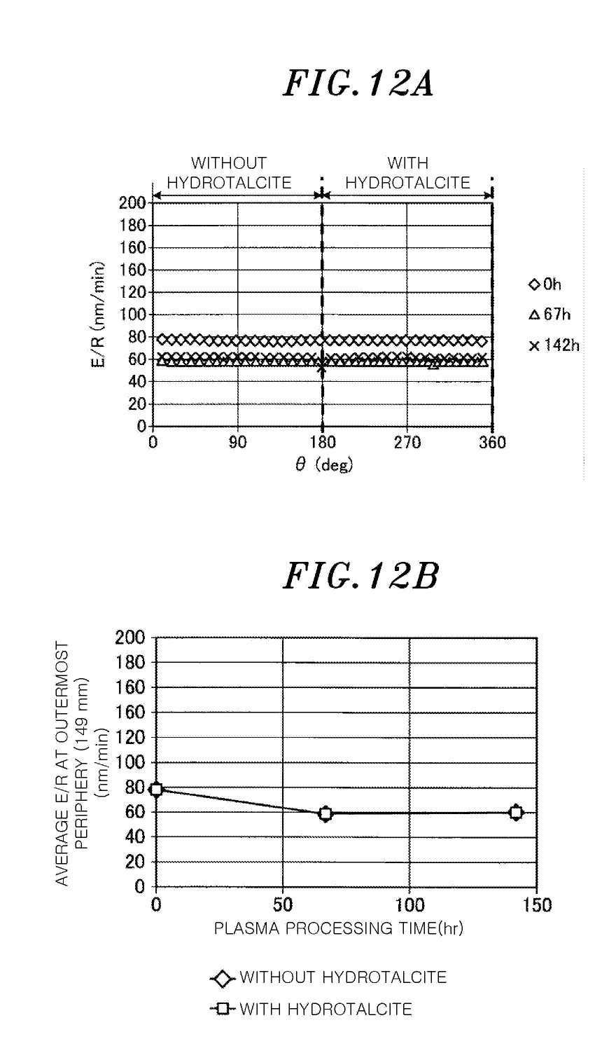

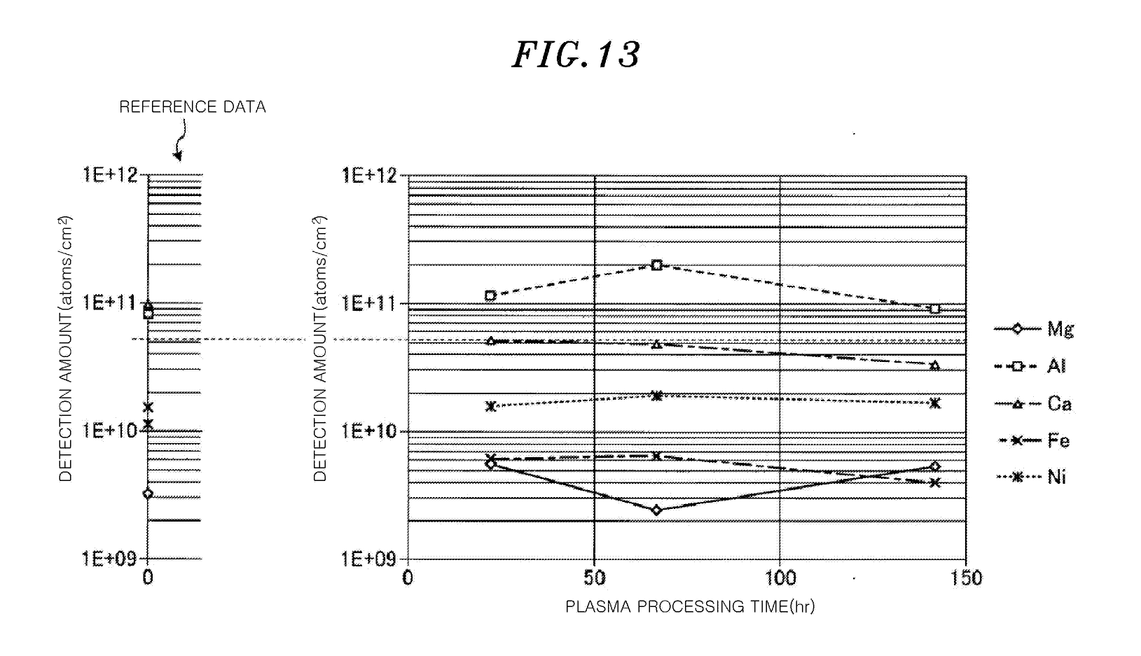

FIG. 12A is a graph showing changes in the etching rate. FIG. 12A shows the etching rates at the positions at the radius of 149 mm from the center by a and at the angle θ of the wafer W in the case of performing the plasma processing for 0 hour (0 h), 67 hours (67 h) and 142 hours (142 h). At the angle θ from 0° to 180°, the protective layer 71a containing no hydrotalcite was formed. At the angle θ from 180° to 360°, the protective layer 71b containing hydrotalcite was formed. As shown in FIG. 12A, the etching rate (E/R) was substantially constant in the case of performing the plasma processing for 0 hour, 67 hours and 142 hours.

FIG. 12B is a graph showing the changes in the etching rate with respect to the plasma processing time. In FIG. 12B, the average of the etching rates at the positions of the radius of 149 mm in the range where the protective layer 71b containing the hydrotalcite is formed is shown as “with hydrotalcite”. The average of the etching rates at the positions of the radius of 149 mm in the range where the protective layer 71a containing no hydrotalcite is formed is shown as “without hydrotalcite”. In FIG. 12B, the graph of “with hydrotalcite” and the graph of “without hydrotalcite” are overlapped.

As can be seen from FIGS. 12A and 12B, the effect on the etching rate can be eliminated by ensuring an appropriate distance from the wafer. In other words, hydrotalcite can contribute to the increase in lifetime of the bonding layer 70 without affecting the processing.

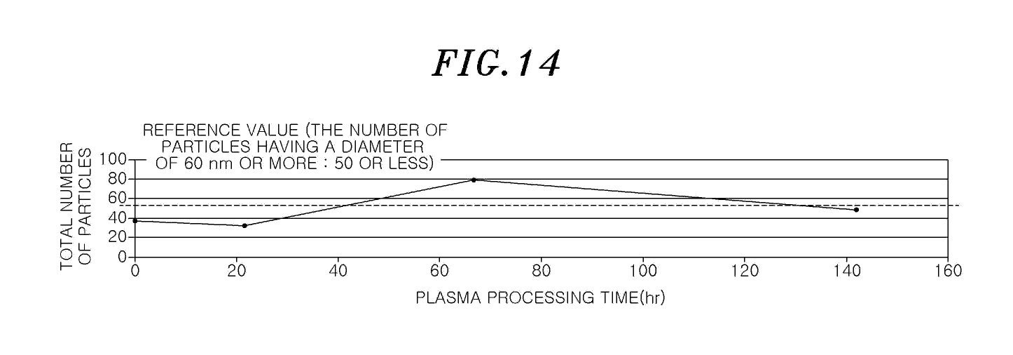

FIG. 13 is a graph showing changes in the amount of contamination with respect to the plasma processing time. The graph of FIG. 13 shows a measurement result of the amount of metal contamination of Mg, Al, Ca, Fe and Ni in the case of performing the plasma processing for 22 hours, 67 hours and 142 hours. At the left side of FIG. 13, the amount of metal contamination of Mg, Al, Ca, Fe, and Ni in the case of forming only the protective layer 71a containing no hydrotalcite is shown as “reference data”. The amount of metal contamination of each element in the case of forming the protective layer containing hydrotalcite is substantially the same as that of the reference data.

As can be seen from FIG. 13, even if the protective layer 71 contains hydrotalcite, the amount of metal contamination is allowable in the plasma processing apparatus 1.

FIG. 14 is a graph showing changes in the amount of particles with respect to the plasma processing time. The graph of FIG. 14 shows the number of particles on the wafer W which was measured in the case of performing the plasma processing for 22 hours, 67 hours and 142 hours. At this time, particles having a diameter of 60 nm or more were measured. In FIG. 14, the case in which the number of particles having a diameter of 60 nm or more is 50 or less is shown as the reference. The amount of particles in each plasma processing is smaller than or substantially the same as that of the reference data.

As can be seen from FIG. 14, even if the protective layer 71 contains hydrotalcite, the influence on the number of particles is small.

The plasma processing apparatus 1 according to the embodiment includes the processing container (processing chamber 10) in which plasma is generated and the bonding layer 70 as a protection target component that is provided in the processing chamber and should be protected from consumption by the plasma. The protective layer 71 containing hydrotalcite is provided on the surface of the bonding layer 70. Accordingly, the plasma processing apparatus 1 can suppress the consumption of the bonding layer 70 by the plasma. As a result, the plasma processing apparatus 1 can reduce the time and effort for the maintenance operation for the bonding layer 70, and the maintenance cost of the plasma processing apparatus 1 can be decreased. Further, in the plasma processing apparatus 1, the downtime in which the plasma processing cannot be performed is decreased, and the decrease in the productivity can be suppressed.

Since hydrotalcite can be obtained at a low cost, the plasma processing apparatus 1 can be manufactured without considerably increasing the manufacturing cost.

### Other Embodiments

While the plasma processing apparatus and the control method according to the first embodiment have been described, the present disclosure is not limited thereto. Hereinafter, other embodiments will be described.

For example, in the plasma processing apparatus 1, the case of suppressing the consumption of the bonding layer 70 by the plasma by providing the protective layer 71 on the side surface of the bonding layer 70 has been described as an example. However, the present disclosure is not limited thereto. In one example of the embodiment of the plasma processing apparatus 1, the bonding layer 70 may contain hydrotalcite, instead of providing the protective layer 71 on the side surface of the bonding layer 70. In that case as well, in the plasma processing apparatus 1, the consumption of the bonding layer 70 by the plasma can be suppressed because F is adsorbed by hydrotalcite contained in the bonding layer 70. Further, in the plasma processing apparatus 1, by using the bonding layer 70 containing hydrotalcite, the consumption of the bonding layer 70 by the plasma entering the through-holes 65 that are formed through the mounting table 11 to accommodate the pusher pins 66 as well as the consumption of the side portion of the bonding layer 70 can be suppressed. Moreover, in the plasma processing apparatus 1, by providing the bonding layer 70 made of a material containing hydrotalcite, the work for forming the protective layer 71 can be eliminated. Even in the conventional plasma processing apparatus 1, the consumption of the bonding layer 70 by the plasma can be suppressed by providing the bonding layer 70 made of a material containing hydrotalcite at the time of performing a maintenance operation for the bonding layer 70.

In the example of the embodiment of the plasma processing apparatus 1, the case in which the protection target member is the bonding layer 70 has been described as an example. However, the present disclosure is not limited thereto. The protection target member may be any member as long as it should be protected from the consumption by the plasma. For example, the protection target member may be an elastomer such as an O-ring for blocking the plasma, polyetheretherketone (PEEK), silicone, acrylic, epoxy or the like used in the plasma processing apparatus 1. Further, the protection target member may be a bush part such as the pusher pin 66 for vertically moving the wafer W, or a pin part. In addition, a surface coating such as a thermally sprayed film or the like may be formed on the surface of the protection target member to protect the protection target member from the plasma. The protection target member may contain hydrotalcite, or a protective layer containing hydrotalcite may be formed on the surface of the protection target member. For example, an elastomer such as an O-ring or the like may be made of a material containing hydrotalcite. In the case of forming a thermally sprayed film on the surface of the protection target member, the thermally sprayed film containing hydrotalcite may be formed on the surface of the protection target member.

<Base>

For example, in the first embodiment, the case in which the mounting table 11 is made of a material having a thermal expansion coefficient lower than that of aluminum has been described. However, the present disclosure is not limited thereto. For example, the mounting table 11 may be a conductive member made of aluminum or the like (linear thermal expansion coefficient of Al: approximately 23.5×10⁻⁶ (cm/cm/degree)) as a lower electrode.

While the present disclosure has been shown and described with respect to the embodiments, it will be understood by those skilled in the art that various changes and modifications may be made without departing from the scope of the present disclosure as defined in the following claims.

What is claimed is:

1. A plasma processing apparatus comprising:
a processing chamber in which plasma is generated; and
a protection target member which is provided in the processing chamber and needs to be protected from consumption by the plasma,
wherein the protection target member is made of a material having a property of integrating radicals and/or anions or a protective layer containing the material is provided on a surface of the protection target member.

2. The plasma processing apparatus of claim 1, wherein the material is hydrotalcite.

3. The plasma processing apparatus of claim 2, wherein the protection target member contains hydrotalcite at a volume percent concentration of 0.5 to 90 vol %, or a protective layer containing hydrotalcite at a volume percent concentration of 0.5 to 90 vol % is formed on a surface of the protection target member.

4. The plasma processing apparatus of claim 1, wherein the material is any one of inorganic nanosheet, layered niobium titanate, and mineral having an ion adsorption property.

5. The plasma processing apparatus of claim 1, wherein the protection target member is an elastomer.

6. The plasma processing apparatus of claim 5, wherein the elastomer is PEEK, silicone, acrylic, or epoxy.

7. The plasma processing apparatus of claim 1, wherein the protection target member is an O-ring, a bush part, a pin part, or a surface coating.
